(19) United States
(12) Patent Application Publication
(10) Pub. No.: US 2026/0361116 A1
(43) Pub. Date: Nov. 12, 2026

(54) DYNAMIC THERMAL MANAGEMENT OF PARALLEL UNINTERRUPTIBLE POWER SUPPLIES

(71) Applicant: Vertiv Corporation, Westerville, OH (US)

(72) Inventors: Stefano Pecorari, Modena (IT); Brian Cogar, Mansfield, OH (US)

(21) Appl. No.: 19/660,018

(22) Filed: Apr. 27, 2026

Related U.S. Application Data
(60) Provisional application No. 63/795,950, filed on Apr. 28, 2025.

(51) Int. Cl. H02J 9/06; H05K 7/20

(52) U.S. Cl. CPC H02J 9/06; H05K 7/20909; H05K 7/20945

(57) ABSTRACT

A system for managing power distribution is disclosed. The system includes a plurality of uninterruptible power supplies operating in parallel to provide power to one or more loads and a plurality of temperature sensors. The various temperature sensors are associated with corresponding ones of the plurality of uninterruptible power supplies, and are configured to generate temperature readings corresponding to a current temperature associated with their corresponding one of the plurality of uninterrupted power supplies. A control system is configured to, in response to a particular temperature reading exceeding a threshold value, reducing an amount of power provided by the corresponding one of the plurality of power supplies, and further configured to redistribute respective amounts of power provided by other ones of the plurality of power supplies.

### CROSS-REFERENCE TO RELATED APPLICATIONS

This non-provisional application claims priority to U.S. provisional application no. 63/195,950 filed Apr. 28, 2025, the entire content of which is incorporated herein by reference.

### BACKGROUND

### 1. Field

The present disclosure is directed to power supplies, and more particularly, to the thermal management of uninterruptible power supplies coupled in parallel.

### 2. Description of Related Art

For various organizations, certain infrastructure may be deemed critical and thus require power to be received without interruptions. Accordingly, uninterruptible power supply (UPS) system may be implemented. UPS systems are used in various industries and applications to provide backup power and protect critical equipment from power disturbances. UPS systems may be used in data centers and IT infrastructure, industrial/manufacturing application, hospitals, and a host of other organizations that utilize critical powered infrastructure.

A UPS provides backup power and protects equipment from power disturbances to provide continuous operation during events such as power failures, power surges, and so on. A typical UPS includes a rectifier/charger to convert AC power to DC power, a battery that stores energy to provide backup power (and is charged by the rectifier/charger), an inverter to convert stored DC power from the battery to power suitable for the supplied equipment, a bypass switch, and surge protection/voltage regulation to filter out power spikes, surges, and voltage fluctuations.

### SUMMARY

The present disclosure is directed to a system for dynamic thermal power management for a plurality of parallel-connected UPSs. In one embodiment, a system includes a plurality of UPSs connected in parallel to provide power to one or more loads. The system further includes a plurality of temperature sensors, each of which may be associated with a given one of the one or more UPSs, and each of which may generate temperature readings. A control system is coupled to receive temperature readings from the various temperature sensors. In response to a particular temperature sensor providing a temperature reading that exceeds a threshold, the control system may reduce the power output from the corresponding UPS, and may further re-distribute the power provided by other ones of the UPSs (e.g., increasing the power output of one or more).

In addition to temperature sensor inputs, the control system may receive inputs from other sensors as well. For example, the control system may receive inputs regarding the speed and status of cooling fans associated with the UPSs to detect deviations in fan operation that could lead to cooling issues. Power measurements may be received from the various UPSs to evaluate power distribution to the load. With regard to the temperature sensors, multiple sensors may be provided for each of the UPSs, such as on heatsinks, power modules, and so on.

### BRIEF DESCRIPTION OF THE DRAWINGS

The above and/or other aspects will become apparent and more readily appreciated from the following description of example embodiments, taken in conjunction with the accompanying drawings, in which:

FIG. 1 is a block diagram illustrating one embodiment of a power distribution system using a plurality of parallel-connected uninterruptible power supplies.

FIG. 2 is a block diagram illustrating one embodiment of an uninterruptible power supply per the disclosure.

FIG. 3 is a flow diagram illustrating one embodiment of a method for operating a power distribution system in accordance with the disclosure.

FIG. 4 is a flow diagram illustrating another embodiment of a method for operating a power distribution system in accordance with the disclosure.

### DETAILED DESCRIPTION

Reference will now be made in detail to example embodiments which are illustrated in the accompanying drawings, wherein like reference numerals refer to like elements throughout. In this regard, the example embodiments may have different forms and may not be construed as being limited to the descriptions set forth herein.

It will be understood that the terms “include,” “including,” “comprise,” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be further understood that, although the terms “first,” “second,” “third,” etc., may be used herein to describe various elements, components, regions, layers and/or sections, these elements, components, regions, layers and/or sections may not be limited by these terms. These terms are only used to distinguish one element, component, region, layer or section from another element, component, region, layer or section.

As used herein, the term “and/or” includes any and all combinations of one or more of the associated listed items. Expressions such as “at least one of,” when preceding a list of elements, modify the entire list of elements and do not modify the individual elements of the list.

Various terms are used to refer to particular system components. Different companies may refer to a component by different names – this document does not intend to distinguish between components that differ in name but not function.

Matters of these example embodiments that are obvious to those of ordinary skill in the technical field to which these example embodiments pertain may not be described herein in detail.

In the implementation of power supply topologies in setting such as data centers or industrial applications, it is desired to optimize both cost and footprint of the power supplies. In some cases, where the cost and footprint cannot be optimized, it is possible that the implementation will not permit full-rated power operation is an issue with cooling the power supply electronics arises. This may result in the need to limit or reduce the power output from the power supplies to prevent them from exceeding thermal limitations.

Cooling effectiveness for power supplies may be reduced by various mechanisms. For example, cooling fans that fail or run at a reduced speeds can reduce cooling effectiveness. Uneven power sharing among parallel devices internal to a given power supply can also reduce cooling effectiveness, as can degradation of thermal interfaces between the power electronics device and corresponding heatsinks. Having the ability to manage power between parallel power converters when such conditions occur can result in maximizing the power capability of the system until proper maintenance can be performed to resolve the issue.

The present disclosure is directed to a system for managing power distribution that is designed to overcome the issues discussed above. The system may quickly redistribute power provided to a load among a plurality of parallel-coupled uninterruptible power supplies (UPSs) when thermal issues arise. By intelligently redistributing power among parallel-connected power supplies, using various power sharing controls, the system may maintain full or near-full power capability, optimizing performance and reducing the risk of down time. This approach may also, over time, extend the operational life of the power supplies and may further enhance system reliability. Various embodiments of such a system are now discussed in further detail.

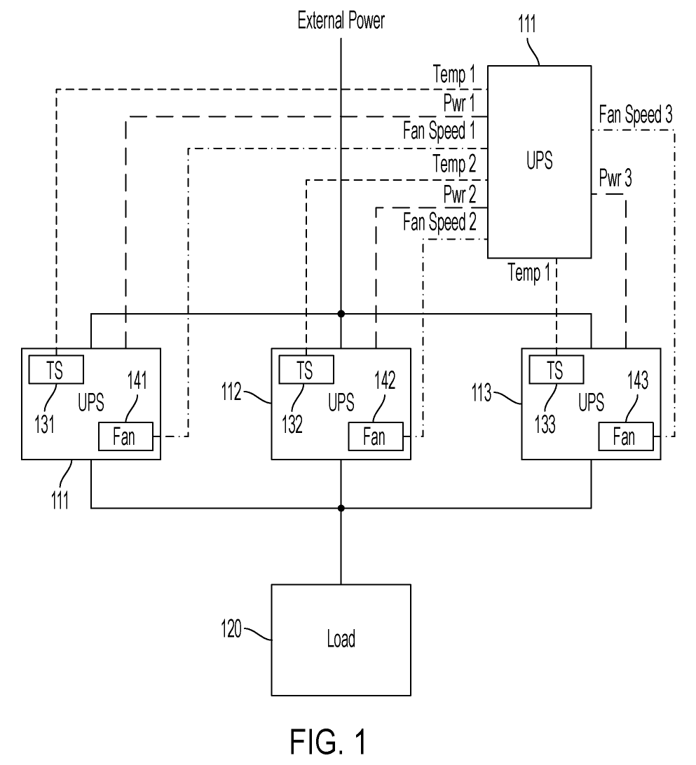

FIG. 1 is a block diagram illustrating one embodiment of a power distribution system using a plurality of parallel-connected uninterruptible power supplies (UPSs). In the embodiment shown, system 100 includes a UPS 111, UPS 112, and UPS 113, each of which is coupled in parallel with one another between an external power source and a load circuit 120. In some embodiments, additional load circuits may be present to receive power from the parallel coupled power supplies. Furthermore, while three instances of a UPS are shown here, the number of instances of a UPS coupled in parallel between the external power source and one or more load circuits may be different.

Each of UPS 111, UPS 112, and UPS 113 in the embodiment shown includes at least one temperature sensor 131 and at least one fan 142. In practice, many embodiments of a UPS may include multiple temperature sensors placed in various locations within the power supply, as well as multiple cooling fans to circulate air around the power electronics therein to carry away heat generated thereby. In some embodiments, UPS 111, 112, and 113 may be substantially identical power supplies. However, embodiments in which there are differences between various ones of the parallel-connected power supplies are possible and contemplated.

Controller 110 as shown here is coupled to each of UPS 111, 112, and 113, and is configured to carry out various control functions with regard to the power supplies. From each power supply, controller 110 as shown here is coupled to receive temperature, power, and fan speed inputs. The temperature inputs are provided from the one or more temperature sensors in each of the power supplies and may be compared to various temperature thresholds to ensure that the power supplies are operating within safe limits, or to take action if they are not. For example, if a temperature reading associated with a particular one of the power supplies is above a threshold considered safe, controller 110 may reduce the power provided to the load by that power supply and increase the power provided to the load by one or more other power supplies.

With regard fan inputs, the controller 110 may monitor the respective speeds of the various fans, and may detect deviations that may impact cooling efficiency. For example, if a fan associated with a particular power supply is running slower than it should for a given temperature reading, controller 110 may operate to increase the speed of that fan, reduce the amount of power supplied by that power supply, or both.

With regard to the power input, controller 110 may receive power measurements indicative of the amount of power provided to the load by each of the power supplies and may further redistribute that power to maintain operation within specified limits (e.g., temperature limits). For example, if controller 110 receives consistently higher temperature readings from one power supply than the remaining power supplies (even if these readings are otherwise within specified limits), it may redistribute power to other power supplies reporting lower operating temperatures. In another example, controller 110 may redistribute power provided by the various power supplies with the goal of equalizing the temperature outputs among all of them.

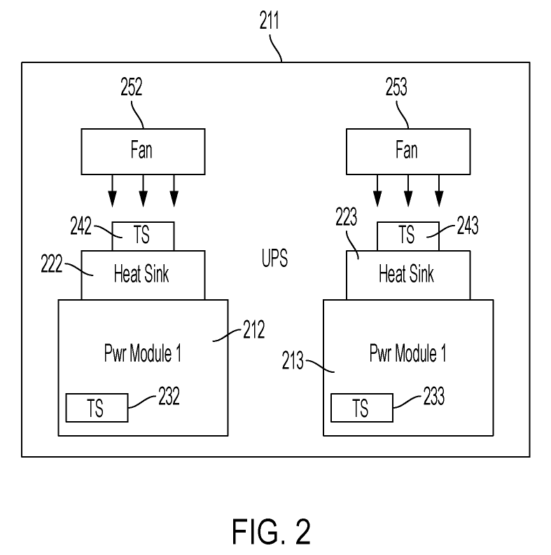

FIG. 2 is a block diagram illustrating one embodiment of an uninterruptible power supply per the disclosure. In the embodiment shown, UPS 211 includes power modules 212 and 213, which may convert the incoming external power to power provided to the load. For example, a given power module may receive AC power at a first voltage and output DC power at a second, different voltage. The power modules 212 and 213, and thus their corresponding power supplies, may be of various types such as SMS (Single Module System) or MMS (Multiple Module System) type power supplies. Furthermore, UPS 211 may comprise a single module UPS having internal power modules connected in parallel.

Power modules 212 and 213 each include temperature sensors 232 and 233, respectively. In practice, multiple temperature sensors may be distributed around each of the power modules, particularly to areas where significant heat generation is expected (e.g., on power electronics). Furthermore, power modules 212 and 213 are coupled to heat sink 222 and 223, respectively, which may draw heat away from power electronics within their corresponding power modules. Temperature sensors 242 and 243 are implemented on heat sinks 222 and 223, respectively, and also provide temperature readings to a controller. It is noted that the temperature thresholds associated with various temperatures may be different. For example, a heat sink may be expected to absorb a significantly greater amount of heat than other components of a correspondingly coupled power module. Accordingly, temperatures from temperature sensors coupled to a heat sink may be compared to different thresholds than other temperature sensors.

Power modules 212 and 213 are associated with fans 252 and 253, respectively. These fans may blow air across their respective power modules to provide further cooling of the components therein. The speeds of these fans may be both monitored and controlled to optimize their cooling effect. It is noted that other fans may also be present at various locations within a given embodiment of a power supply.

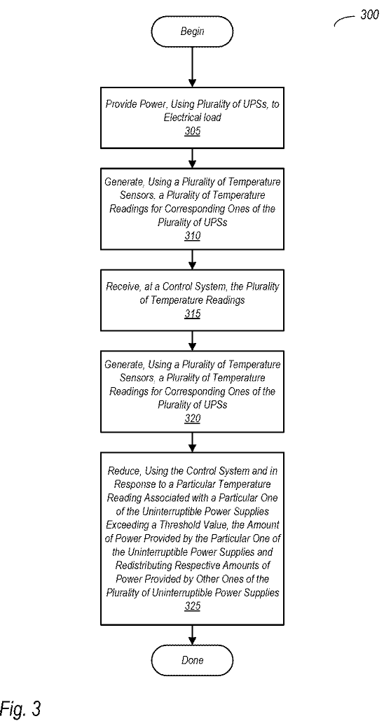

FIG. 3 is a flow diagram illustrating one embodiment of a method for operating a power distribution system in accordance with the disclosure. Method 300 may be carried out by various embodiments of the apparatus discussed above. Other embodiments of an apparatus capable of carrying out Method 300 are considered to fall within the scope of this disclosure.

Method 300 includes providing power, using a plurality of UPSs, to an electrical load (block 305). The UPSs may be coupled in parallel between an external power source and the electrical load. The electrical load may be, e.g., a data server or plurality thereof, industrial equipment, or any other suitable electrical load.

The method further includes generating, using a plurality of temperature sensors, a plurality of temperature readings for corresponding ones of the plurality of UPSs (block 310). The temperature sensors may be distributed around each UPS, including in and around power electronics thereof, on heatsinks, and so on. The method also includes receiving, at a control system, the plurality of temperature readings from the temperature sensors where they were generated (block 315).

The method further includes generating a plurality of comparisons using the plurality of temperature readings (block 320). Each of the comparison results may be obtained by comparing temperature readings from the various temperature sensors to one or more temperature thresholds. In some implementations, the thresholds may be different for temperature sensors placed at different locations. Such thresholds may be based on the expected thermal output at a sensor’s location and the corresponding safe limits of thermal output.

Method 300 further includes reducing, by the control system, the amount of power provided by a particular UPS in response to a temperature reading from a corresponding sensor exceeding a threshold value (block 325). In conjunction with the reduction in power by the particular UPS, the control system may redistribute power among the other UPSs such that the power provided by at least one of the UPSs is increased. In this manner, the amount of power provided to the electrical load may be maintained while preventing the particular UPS from being damaged due to overheating.

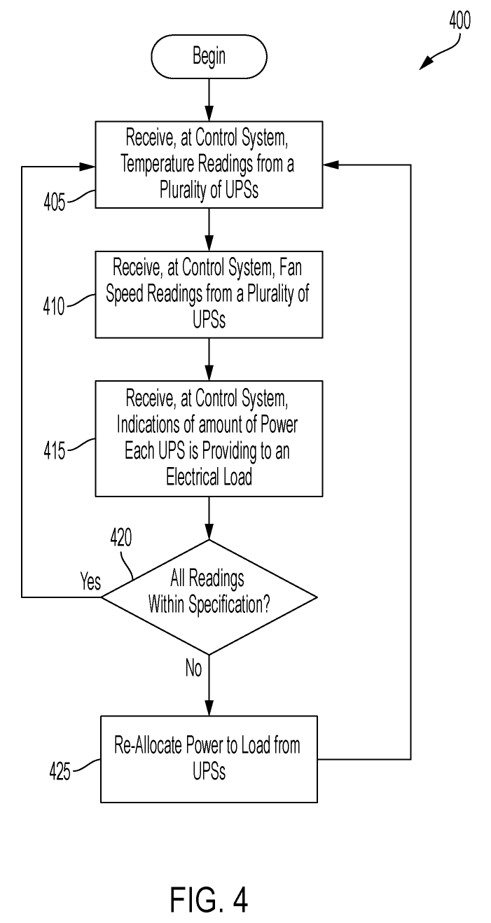

FIG. 4 is a flow diagram illustrating another embodiment of a method for operating a power distribution system in accordance with the disclosure. Method 400 may be carried out by various embodiments of the apparatus discussed above. An apparatus embodiment capable of performing Method 400, but not otherwise discussed herein, is also considered to fall within the scope of this disclosure.

Method 400 includes receiving, at a control system, temperature readings from a plurality of UPSs coupled between an external power source and an electrical load (block 405). The method further includes receiving, at the control system, a plurality of fan speed reading from fans associated with ones of the plurality of UPSs (block 410), and receiving, at the control system, indications of respective amounts of power provided by each UPS to the electrical load (block 415).

Using the various readings, the control system may determine if the readings are within specification (block 420). For example, the control system may compare fan speed readings to expected values, temperature readings to various temperature threshold, and so on. If the readings are all within specification (block 427, yes), Method 400 returns to block 405 and continues. If one or more of the readings are out of specification (block 425, no), the control system may re-allocate power provided to the load from the various ones of the UPSs (block 425). For example, the control system may reduce the power provided by one of the UPSs from which the out-of-specification reading was obtained, and increase the power provided by another one of the UPSs. The control system may also carry out other functions, such as adjusting fan speeds.

It may be understood that the example embodiments described herein may be considered in a descriptive sense only and not for purposes of limitation. Descriptions of features or aspects within each example embodiment may be considered as available for other similar features or aspects in other example embodiments.

While example embodiments have been described with reference to the figures, it will be understood by those of ordinary skill in the art that various changes in form and details may be made therein without departing from the spirit and scope as defined by the following claims.

What is claimed is:

1. A system for managing power distribution, the system comprising:
a plurality of uninterruptible power supplies operating in parallel to provide power to one or more loads;
a plurality of temperature sensors, wherein ones of the plurality of temperature sensors are associated with corresponding ones of the plurality of uninterruptible power supplies, wherein ones of the plurality of temperature sensors are configured to generate temperature readings corresponding to a current temperature associated with their corresponding one of the plurality of uninterrupted power supplies; and
a control system configured to, in response to a particular temperature reading associated with a particular one of the plurality of uninterruptible power supplies exceeding a threshold value, reducing an amount of power provided by the particular one of the plurality of uninterruptible power supplies and redistributing respective amounts of power provided by other ones of the plurality of uninterruptible power supplies.

2. The system of claim 1, wherein the control system is configured to track respective speeds of a plurality of cooling fans associated with ones of the plurality of uninterruptible power supplies.

3. The system of claim 1, wherein one or more of the plurality of temperature sensors are implemented on a heatsink associated with one of the plurality of uninterruptible power supplies.

4. The system of claim 1, wherein one or more of the plurality of temperature sensors are implemented in a power module associated with one of the plurality of uninterruptible power supplies.

5. The system of claim 1, wherein the control system is configured to receive power measurements indicative of power provided to a load circuit by each of the plurality of uninterruptible power supplies.

6. The system of claim 1, wherein one or more of the plurality of uninterruptible power supplies is a static maintenance switch (SMS) power supply.

7. The system of claim 1, wherein one or more of the plurality of uninterruptible power supplies is a manual maintenance switch (MMS) power supply.

8. A method comprising:
providing power, using a plurality of uninterruptible power supplies, to an electrical load;
generating, using a plurality of temperature sensors, a plurality of temperature readings for corresponding ones of the plurality of uninterruptible power supplies;
receiving, at a control system, the plurality of temperature readings; and
reducing, using the control system and in response to a particular temperature reading associated with a particular one of the plurality of uninterruptible power supplies exceeding a threshold value, an amount of power provided by the particular one of the plurality of uninterruptible power supplies and redistributing respective amounts of power provided by other ones of the plurality of uninterruptible power supplies.

9. The method of claim 8, further comprising tracking, using the control system, respective speeds of a plurality of cooling fans associated with respective ones of the plurality of uninterruptible power supplies.

10. The method of claim 8, wherein generating the plurality of temperature readings comprises generating temperature readings using one or more temperature sensors implemented on a heatsink associated with one of the plurality of uninterruptible power supplies.

11. The method of claim 8, wherein generating the plurality of temperature readings comprises generating temperature readings using one or more temperature sensors implemented in a power module associated with one of the plurality of uninterruptible power supplies.

12. The method of claim 8, further comprising receiving, at the control system, power measurements indicative of respective amounts of power provided to the electrical load by each of the plurality of uninterruptible power supplies.

13. The method of claim 8, wherein at least one of the plurality of uninterruptible power supplies comprises a static maintenance switch (SMS) power supply.

14. The method of claim 8, wherein at least one of the plurality of uninterruptible power supplies comprises a manual maintenance switch (MMS) power supply.

15. An apparatus comprising:
a control system having a plurality of inputs coupled to receive information from ones of a plurality of uninterruptible power supplies coupled in parallel and providing power to an electrical load, wherein the plurality of inputs includes:
a plurality of temperature inputs configured to receive temperature readings associated with ones of the plurality of uninterruptible power supplies; and
a plurality of power inputs configured to receive power readings indicative of an amount of power provided by each of the plurality of uninterruptible power supplies to the electrical load; and
wherein the control system is configured to, in response to a particular temperature reading associated with a particular one of the plurality of uninterruptible power supplies exceeding a threshold value, re-allocate power provided by ones of the plurality of uninterruptible power supplies.

16. The apparatus of claim 15, wherein the plurality of inputs further includes fan-related inputs configured to receive fan speed readings from cooling fans associated with respective ones of the plurality of uninterruptible power supplies, and wherein the control system is configured to use the fan speed readings in conjunction with the temperature readings to determine whether the particular temperature reading exceeds the threshold value.

17. The apparatus of claim 15, wherein at least one of the plurality of temperature inputs is coupled to receive temperature readings from temperature sensors implemented on at least one of:
(a) a heatsink associated with one of the plurality of uninterruptible power supplies, or
(b) a power module associated with one of the plurality of uninterruptible power supplies.

18. The apparatus of claim 15, wherein the control system is configured to re-allocate power by reducing an amount of power provided by the particular one of the plurality of uninterruptible power supplies associated with the particular temperature reading and increasing an amount of power provided by at least one other one of the plurality of uninterruptible power supplies.

19. The apparatus of claim 15, wherein the control system is further configured to compare the temperature readings received via the plurality of temperature inputs to respective temperature threshold values that differ based on sensor location.

20. The apparatus of claim 15, wherein at least one of the plurality of uninterruptible power supplies comprises a static maintenance switch (SMS) power supply or a manual maintenance switch (MMS) power supply.
